(19) United States
(12) Patent Application Publication
(10) Pub. No.: US 2024/0203297 A1
(43) Pub. Date: Jun. 20, 2024

(54) DISPLAY DEVICE

(71) Applicant: Qisda Corporation, Taoyuan City (TW)

(72) Inventors: Chin Fu Lee, Taoyuan City (TW); Szu Fan Chen, Taoyuan City (TW)

(73) Assignee: Qisda Corporation, Taoyuan City (TW)

(21) Appl. No.: 18/507,085

(22) Filed: Nov. 12, 2023

(30) Foreign Application Priority Data
Dec. 14, 2022 (CN) 202211606259.1

(51) Int. Cl. G09F 9/302; G09F 9/33

(52) U.S. Cl. CPC G09F 9/3026; G09F 9/33

(57) ABSTRACT

A display device including a first casing, a second casing, and a connection structure is provided. The connection structure includes a rotation member, a locking assembly, a first locked portion, and a second locked portion. The rotation member is rotatably connected to the first casing. The locking assembly is movably connected to the rotation member and has a first locking portion and a second locking portion. The first locked portion is disposed on the first casing and locked by the first locking portion. The second locked portion is disposed on the second casing and locked by the second locking portion.

### CROSS-REFERENCE TO RELATED APPLICATION

This application claims the priority benefit of China application serial no. 202211606259.1, filed on Dec. 14, 2022. The entirety of the above-mentioned patent application is hereby incorporated by reference herein and made a part of this specification.

### BACKGROUND

### Technical Field

The disclosure relates to a display device and particularly relates to a splicing display device.

### Description of Related Art

A direct view light emitting diode (LED) display is a type of display commonly applied to a large-scale advertising billboard and having the advantage of delivering a rich visual experience to viewers. The direct view LED display is composed of a plurality of LED light boxes spliced together, where the light boxes are generally spliced together in a relatively time-consuming and labor-consuming screw-fastening manner. Existing quick splicing structures are characterized by their complex design and high setup costs, and it is difficult to ensure that there is no gap between two spliced light boxes.

### SUMMARY

The disclosure provides a display device with casings whose simple structures allow mutual splicing without any gap.

In an embodiment of the disclosure, a display device that includes a first casing, a second casing, and a connection structure is provided. The connection structure includes a rotation member, a locking assembly, a first locked portion, and a second locked portion. The rotation member is rotatably connected to the first casing. The locking assembly is movably connected to the rotation member and has a first locking portion and a second locking portion. The first locked portion is disposed on the first casing and locked by the first locking portion. The second locked portion is disposed on the second casing and locked by the second locking portion.

According to an embodiment of the disclosure, the first locked portion is a cylinder, and the first locking portion is a locking hook.

According to an embodiment of the disclosure, the second locked portion is a cylinder, and the second locking portion is a locking hook.

According to an embodiment of the disclosure, the connection structure further includes an elastic member that is disposed on the first locked portion and contacts the first locking portion.

According to an embodiment of the disclosure, the elastic member is sleeved on the first locked portion.

According to an embodiment of the disclosure, the locking assembly includes a first locking member and a second locking member, the first locking member and the second locking member are rotatably connected to the rotation member, the first locking portion is located at the first locking member, and the second locking portion is located at the second locking member.

According to an embodiment of the disclosure, the rotation member is rotatably connected to the first casing along a first rotation axis, the first locking member and the second locking member are rotatably connected to the rotation member along a second rotation axis, and the first rotation axis is parallel to the second rotation axis.

According to an embodiment of the disclosure, the first locking member is adapted to rotate along a first rotation direction to be locked to the first locked portion, the second locking member is adapted to rotate along a second rotation direction to be locked to the second locked portion, and the first rotation direction is opposite to the second rotation direction.

According to an embodiment of the disclosure, the connection structure further includes a pivot shaft, and the first locking member and the second locking member are rotatably connected to the rotation member through the pivot shaft.

According to an embodiment of the disclosure, the connection structure further includes a pivot shaft, and the rotation member is rotatably connected to the first casing through the pivot shaft.

According to an embodiment of the disclosure, the first locking portion applies a locking force to the first locked portion along a first force applying direction, and the second locking portion applies a locking force to the second locked portion along a second force applying direction opposite to the first force applying direction.

According to an embodiment of the disclosure, an edge of the first casing leans against the second casing, and a connection line between the first locked portion and the second locked portion is perpendicular to the edge.

In another embodiment of the disclosure, a display device that includes a first casing, a second casing, and a connection structure is provided. The connection structure includes a rotation member, a first locking member, a second locking member, a first locked portion, and a second locked portion. The rotation member is rotatably connected to the first casing. The first locking member is rotatably connected to the rotation member and has a first locking portion. The second locking member is rotatably connected to the rotation member and has a second locking portion. The first locked portion is disposed on the first casing and locked by the first locking portion. The second locked portion is disposed on the second casing and locked by the second locking portion.

According to another embodiment of the disclosure, the first locked portion is a cylinder, and the first locking portion is a locking hook.

According to another embodiment of the disclosure, the second locked portion is a cylinder, and the second locking portion is a locking hook.

According to another embodiment of the disclosure, the connection structure further includes an elastic member that is disposed on the first locked portion and contacts the first locking portion.

According to another embodiment of the disclosure, the elastic member is sleeved on the first locked portion.

According to another embodiment of the disclosure, the connection structure further includes a pivot shaft, and the rotation member is rotatably connected to the first casing through the pivot shaft.

According to another embodiment of the disclosure, the first locking portion applies a locking force to the first locked portion along a first force applying direction, and the second locking portion applies a locking force to the second locked portion along a second force applying direction opposite to the first force applying direction.

According to another embodiment of the disclosure, an edge of the first casing leans against the second casing, and a connection line between the first locked portion and the second locked portion is perpendicular to the edge.

In light of the foregoing, the connection structure provided in one or more embodiments of the disclosure respectively locks the first locked portion on the first casing and the second locked portion on the second casing through the first locking portion and the second locking portion of the connection structure, so as to closely connect the first casing and the second casing through a locking force. During the process of connecting the first casing and the second casing by applying the connection structure, the second locking portion may easily lock the second locked portion through the rotation member which rotates toward the second casing, and the first locking portion locks the first locked portion through the rotation member which rotates toward the first casing; at the same time, the second casing is pulled toward the first casing, so as to closely connect the first casing and the second casing to each other. As such, the first casing and the second casing with the simple structures may be spliced to each other without generating any gap between the two casings.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a three-dimensional view illustrating some components in a display device according to an embodiment of the disclosure.

FIG. 2 is an enlarged view illustrating a portion of the display device depicted in FIG. 1.

FIG. 3 and FIG. 4 illustrate an operational manner of the connection structure depicted in FIG. 2.

### DESCRIPTION OF THE EMBODIMENTS

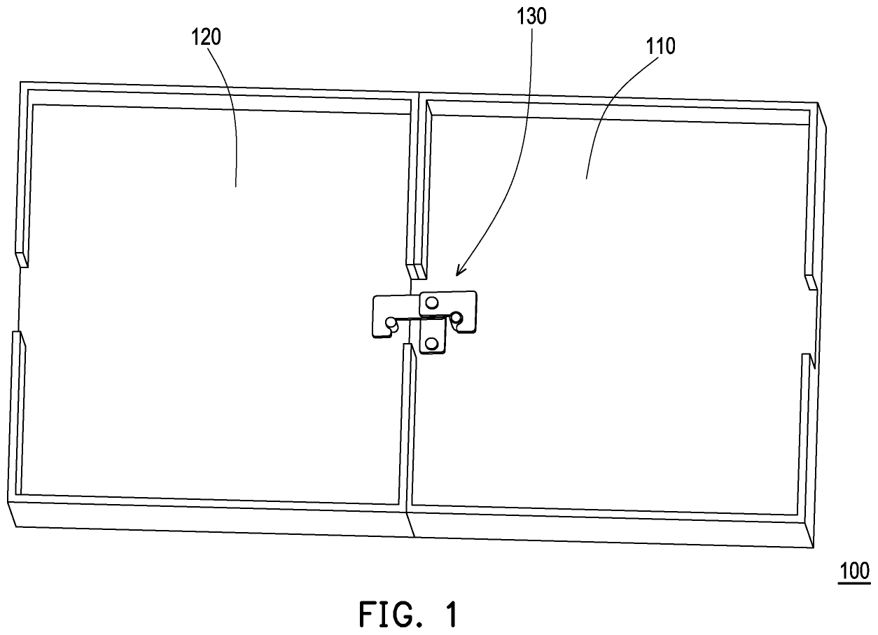

FIG. 1 is a three-dimensional view illustrating some components in a display device according to an embodiment of the disclosure. With reference to FIG. 1, a display device 100 provided in this embodiment includes a first casing 110, a second casing 120, and a connection structure 130. The display device 100 is, for instance, a direct view LED display. The first casing 110 and the second casing 120 are, for instance, light boxes in which an LED array is respectively disposed for displaying images. For clear and concise illustrations, the LED arrays are not shown in the drawings. The first casing 110 and the second casing 120 are spliced to each other through the connection structure 130 to constitute a complete display surface. The number of the first casing 110, the second casing 120, and the connection structure 130 is not limited in the disclosure and may be more than what is disclosed herein, and the first casings 110 and the second casings 120 may be spliced together through a plurality of connection structures 130 arranged in an array.

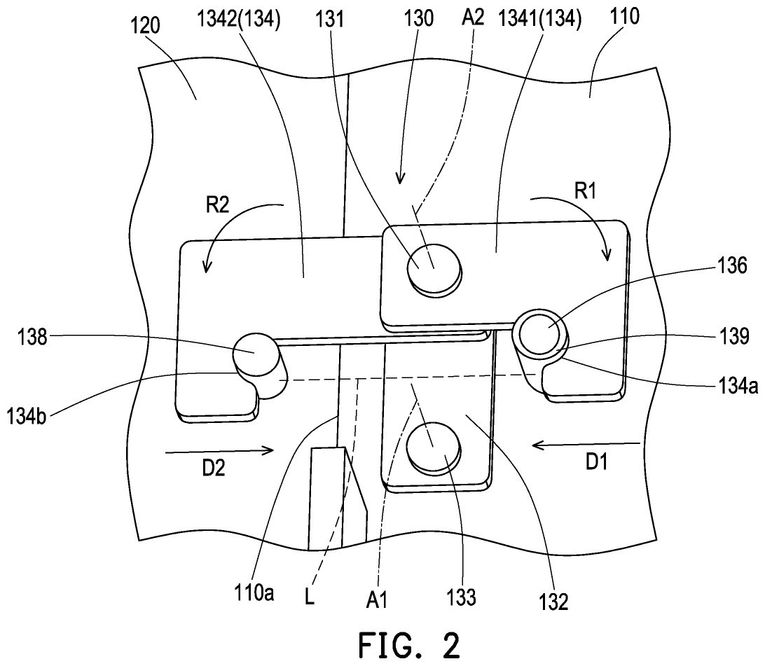

FIG. 2 is an enlarged view illustrating a portion of the display device depicted in FIG. 1. With reference to FIG. 2, the connection structure 130 provided in this embodiment includes a rotation member 132, a pivot shaft 133, a locking assembly 134, a first locked portion 136, and a second locked portion 138. The rotation member 132 is rotatably connected to the first casing 110 along a first rotation axis A1 through the pivot shaft 133. The locking assembly 134 is movably connected to the rotation member 132 and has a first locking portion 134a and a second locking portion 134b. The first locked portion 136 is disposed on the first casing 110 and locked by the first locking portion 134a. The second locked portion 138 is disposed on the second casing 120 and locked by the second locking portion 134b.

As mentioned above, the connection structure 130 provided in this embodiment locks the first locked portion 136 on the first casing 110 and the second locked portion 138 on the second casing 120 through the first locking portion 134a and the second locking portion 134b of the connection structure 130, respectively, so as to closely connect the first casing 110 and the second casing 120 through a locking force.

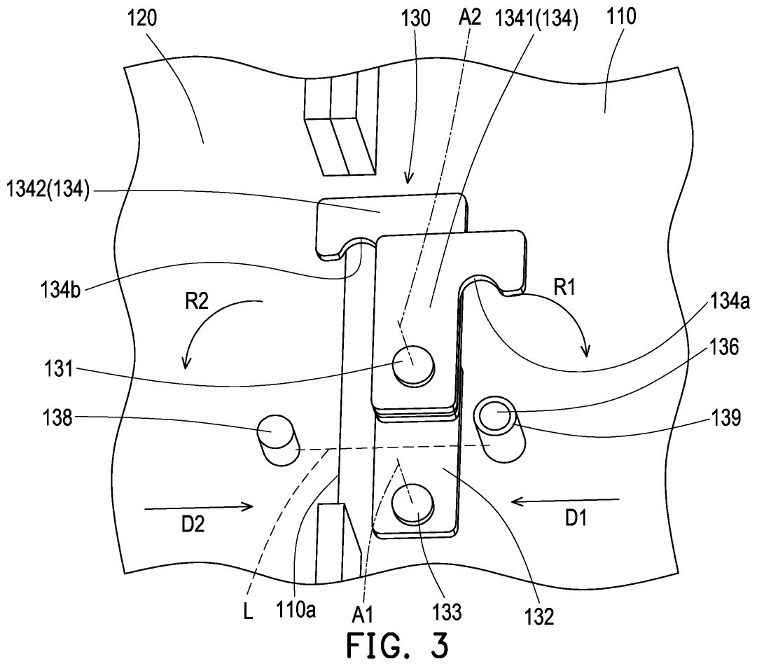

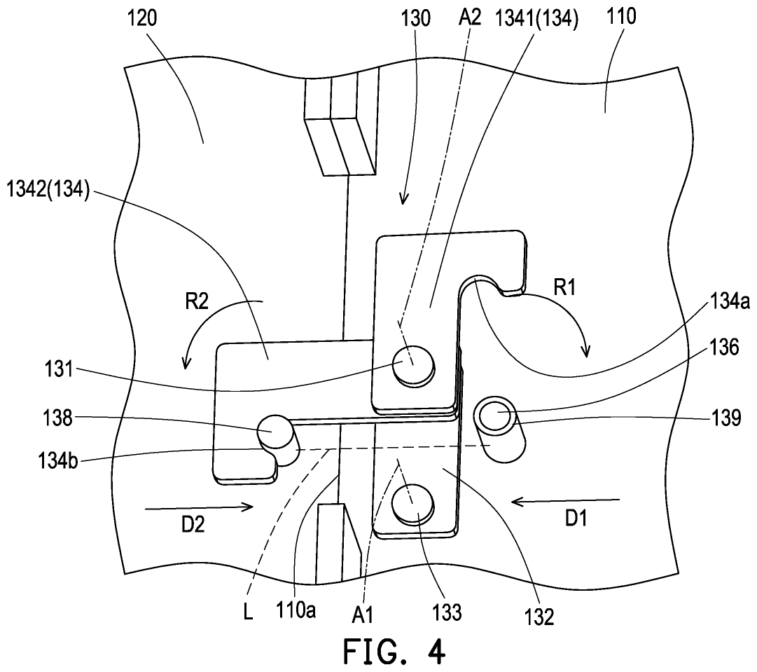

FIG. 3 and FIG. 4 illustrate an operational manner of the connection structure depicted in FIG. 2. Specifically, in the process of connecting the first casing 110 and the second casing 120 by applying the connection structure 130, the second locking portion 134b may easily lock the second locked portion 138 as shown in FIG. 4 through a rotation of the rotation member 132 depicted in FIG. 3 toward the second casing 120, and the first locking portion 134a locks the first locked portion 136 as shown in FIG. 2 through a rotation of the rotation member 132 toward the first casing 110; meanwhile, and the second casing 120 is pulled toward the first casing 110, so as to closely connect the first casing 110 and the second casing 120 as mentioned above. As such, the first casing 110 and the second casing 120 with the simple structures may be spliced to each other without generating any gap between the two casings 110 and 120. Besides, reducing the overall thickness of the device is not subject to the excessive size of the connection structure of the display device 100 and thus may not be difficult, which is beneficial to the design of thinning down the device.

To be specific, in this embodiment, an edge 110a of the first casing 110 leans against the second casing 120, and a connection line L between the first locked portion 136 and the second locked portion 138 is perpendicular to the edge 110a. The first locking portion 134a applies a locking force to the first locked portion 136 along a first force applying direction D1 perpendicular to the edge 110a, and the second locking portion 134b applies a locking force to the second locked portion 138 along a second force applying direction D2 opposite to the first force applying direction D1. Thereby, the connection structure 130 is able to firmly secure the first casing 110 and the second casing 120.

In this embodiment, the first locked portion 136 and the second locked portion 138 are, for instance, cylinders, and the first locking portion 134a and the second locking portion 134b are, for instance, locking hooks that may be hooked to the cylinders. In other embodiments, the first locked portion 136, the second locked portion 138, the first locking portion 134a, and the second locking portion 134b may be structures of other appropriate forms, which should not be construed as a limitation in the disclosure. For instance, the first locked portion 136 and the second locked portion 138 may both be the locking hooks, and the first locking portion 134a and the second locking portion 134b may both be the corresponding cylinders. Alternatively, the first locked portion 136 and the second locked portion 138 may both be latches, and the first locking portion 134a and the second locking portion 134b may both be corresponding latching holes. In another alternative, the first locked portion 136 and the second locked portion 138 may both be the latching holes, and the first locking portion 134a and the second locking portion 134b may both be the corresponding latches.

The connection structure 130 provided in this embodiment further includes an elastic member 139. The elastic member 139 is disposed on the first locked portion 136 and contacts the first locking portion 134a, so that the connection structure 130 may connect the first casing 110 and the second casing 120 more firmly and tightly through the elastic deformation of the elastic member 139. The elastic member 139 is, for instance, ed on the first locked portion 136, which should however not be construed as a limitation in the disclosure.

The composition of the locking assembly 134 provided in this embodiment is described below. In this embodiment, the locking assembly 134 includes a first locking member 1341 and a second locking member 1342, and the connection structure 130 further includes a pivot shaft 131. The first locking member 1341 and the second locking member 1342 are rotatably connected to the rotation member 132 along a second rotation axis A2 parallel to the first rotation axis A1 through the pivot shaft 131, the first locking portion 134a is located at the first locking member 1341, and the second locking portion 134b is located at the second locking member 1342. The first locking member 1341 depicted in FIG. 4 is adapted to rotate along a first rotation direction R1, so as to allow the first locking portion 134a to lock the first locked portion 136 as shown in FIG. 2; the second locking member 1342 depicted in FIG. 3 is adapted to rotate along a second rotation direction R2 opposite to the first rotation direction R1, so as to allow the second locking portion 134b to lock the second locked portion 138 as shown in FIG. 4. In other embodiments, the locking assembly may be of other forms, which should not be construed as a limitation in the disclosure.

To sum up, the connection structure provided in one or more embodiments of the disclosure respectively locks the first locked portion on the first casing and the second locked portion on the second casing through the first locking portion and the second locking portion of the connection structure, so as to closely connect the first casing and the second casing through the locking force. In the process of connecting the first casing and the second casing by applying the connection structure, the second locking portion may easily lock the second locked portion through the rotation of the rotation member toward the second casing, and the first locking portion may lock the first locked portion through the rotation of the rotation member toward the first casing; at the same time, the second casing is pulled toward the first casing, so as to closely connect the first casing and the second casing to each other as mentioned above. As such, the first casing and the second casing with the simple structures may be spliced together without generating any gap between the casings according to one or more embodiments of the disclosure. Additionally, reducing the overall thickness of the device is not subject to the excessive size of the connection structure of the display device and thus may not be difficult, which is beneficial to the design of thinning down the device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
a first casing;
a second casing; and
a connection structure, comprising:
a rotation member, rotatably connected to the first casing;
a locking assembly, movably connected to the rotation member and having a first locking portion and a second locking portion;
a first locked portion, disposed on the first casing and locked by the first locking portion; and
a second locked portion, disposed on the second casing and locked by the second locking portion.

2. The display device according to claim 1, wherein the first locked portion is a cylinder, and the first locking portion is a locking hook.

3. The display device according to claim 1, wherein the second locked portion is a cylinder, and the second locking portion is a locking hook.

4. The display device according to claim 1, wherein the connection structure further comprises an elastic member disposed on the first locked portion and contacting the first locking portion.

5. The display device according to claim 4, wherein the elastic member is sleeved on the first locked portion.

6. The display device according to claim 1, wherein the locking assembly comprises a first locking member and a second locking member, the first locking member and the second locking member are rotatably connected to the rotation member, the first locking portion is located at the first locking member, and the second locking portion is located at the second locking member.

7. The display device according to claim 6, wherein the rotation member is rotatably connected to the first casing along a first rotation axis, the first locking member and the second locking member are rotatably connected to the rotation member along a second rotation axis, and the first rotation axis is parallel to the second rotation axis.

8. The display device according to claim 6, wherein the first locking member is adapted to rotate along a first rotation direction to be locked to the first locked portion, the second locking member is adapted to rotate along a second rotation direction to be locked to the second locked portion, and the first rotation direction is opposite to the second rotation direction.

9. The display device according to claim 6, wherein the connection structure further comprises a pivot shaft, and the first locking member and the second locking member are rotatably connected to the rotation member through the pivot shaft.

10. The display device according to claim 1, wherein the connection structure further comprises a pivot shaft, and the rotation member is rotatably connected to the first casing through the pivot shaft.

11. The display device according to claim 1, wherein the first locking portion applies a locking force to the first locked portion along a first force applying direction, and the second locking portion applies a locking force to the second locked portion along a second force applying direction opposite to the first force applying direction.

12. The display device according to claim 1, wherein an edge of the first casing leans against the second casing, and a connection line between the first locked portion and the second locked portion is perpendicular to the edge.

13. A display device, comprising:
a first casing;
a second casing; and
a connection structure, comprising:
a rotation member, rotatably connected to the first casing;
a first locking member, rotatably connected to the rotation member and having a first locking portion;
a second locking member, rotatably connected to the rotation member and having a second locking portion;
a first locked portion, disposed on the first casing and locked by the first locking portion; and
a second locked portion, disposed on the second casing and locked by the second locking portion.

14. The display device according to claim 13, wherein the first locked portion is a cylinder, and the first locking portion is a locking hook.

15. The display device according to claim 13, wherein the second locked portion is a cylinder, and the second locking portion is a locking hook.

16. The display device according to claim 13, wherein the connection structure further comprises an elastic member disposed on the first locked portion and contacting the first locking portion.

17. The display device according to claim 16, wherein the elastic member is sleeved on the first locked portion.

18. The display device according to claim 13, wherein the connection structure further comprises a pivot shaft, and the rotation member is rotatably connected to the first casing through the pivot shaft.

19. The display device according to claim 13, wherein the first locking portion applies a locking force to the first locked portion along a first force applying direction, and the second locking portion applies a locking force to the second locked portion along a second force applying direction opposite to the first force applying direction.

20. The display device according to claim 13, wherein an edge of the first casing leans against the second casing, and a connection line between the first locked portion and the second locked portion is perpendicular to the edge.
